(19) United States
(12) Patent Application Publication
(10) Pub. No.: US 2012/0243148 A1
(43) Pub. Date: Sep. 27, 2012

(54) Decorative visual screen cover

(76) Inventors: Rose S Vadnai, Chicago, IL (US); Ruben E Vadnai, Chicago, IL (US)

(21) Appl. No.: 13/065,534

(22) Filed: Mar. 24, 2011

(51) Int. Cl. H05K 5/03

(52) U.S. Cl. 361/679.01

(57) ABSTRACT

The invention provides for a cover and a method of its use for improving the appearance of a tv screen when it is not in use. The cover has a front section which is decorated such that it has a much more pleasing appearance than an uncovered tv screen. The rear of the cover is constructed and arranged to hold the cover flush against the screen and is especially shaped to accommodate the particular features of modern tv screens.

### CROSS-REFERENCE TO RELATED APPLICATIONS

None.

### STATEMENT REGARDING FEDERALLY SPONSORED RESEARCH OR DEVELOPMENT

Not Applicable.

### BACKGROUND OF THE INVENTION

This invention relates to a decorative cover sized to tastefully cover or conceal a visual display screen or monitor. The use of flat visual display screen monitors has become much more prevalent in the past few years. Items such as flatscreen, plasma or LCD screens are expensive items that are displayed without regard to gracefully blend in with the room's esthetic. Existing tv covers have generally been made to protect a tv screen, typically outdoors, and are often made of a protective vinyl-like material.

The problem with the existing covers is that while they are protective they are not decorative to be used inside a home and blend in with the decor and home environment. One attempt to address this was a contestant in the Sew Useful Sewing contest. The contestant's idea was to cover the tv with duck cloth or canvas that is lined with heavyweight fusible interfacing. The contestant also suggested decorating the cover with pieces of material in a design. This attempt however was deficient because it depended on cumbersome attached artwork which prevented the cover from being easily stored or folded when removed.

Therefore it clear that there is utility and novelty in an improved decorative tv cover. The art described in this section is not intended to constitute an admission that any patent, publication or other information referred to herein is “prior art” with respect to this invention, unless specifically designated as such. In addition, this section should not be construed to mean that a search has been made or that no other pertinent information as defined in 37 C.F.R. §1.56(a) exists. Any and all patents, patent applications, and other references cited by this application are hereby incorporated by reference in their entirety.

### BRIEF SUMMARY OF THE INVENTION

At least one embodiment of the invention is directed towards a method for improving the esthetic appearance of a display screen. The method includes the step of positioning over the display screen a decorative cover, the cover comprising: i) a front section constructed out of a flexible material, ii) a rear section, the rear section having an upper section, a lower section, two side sections, each section engaged to the front surface and defining an opening, the opening positioned to surround a wall supporting member engaged to the display screen, iii) the front section constructed and arranged to have sufficient tension to fit smoothly against the display screen's surface while positioned within a substantially vertical plane without any visible bunching up of the front section or ill-fitting irregularities, iv) the upper section having a larger surface area than the bottom section and thereby facilitating in holding the front section smoothly against the display screen's surface, and v) the front section having a decorative appearance.

### BRIEF DESCRIPTION OF THE DRAWINGS

FIG. 1 illustrates a front view of a display screen cover.

FIG. 2 illustrates a rear view of one kind of display screen cover.

FIG. 3 illustrates a rear view of another kind of display screen cover.

FIG. 4 illustrates a front view of a cut out of material useful in creating a display screen cover.

### DETAILED DESCRIPTION OF THE INVENTION

The present invention is a decorative and tastefully concealing cover for a visual display screen or monitor. It is designed to blend in with the home décor and camouflages the television as a piece of art. Unlike the prior art, this invention is made of decorative material. In at least one embodiment, the cover is soft and flexible and does not require fusible interfacing. It can be folded easily and requires no special care for storage.

In at least one embodiment the invention comprises a front cover and a suspending member. The front cover covers at least a portion of a visual display screen. The suspending member holds the cover in place relative to the monitor. The cover does not visibly extend beyond the borders of the visual display screen and range of motion relative to the visual display screen is limited. In one embodiment the visual display screen cover has an aesthetically pleasing appearance. In one embodiment the visual display screen cover is color coordinated with the surrounding décor or environment.

In at least one embodiment the visual display screen cover camouflages the visual display screen as a work of art.

In at least one embodiment the visual display screen cover camouflages the visual display screen as a tapestry.

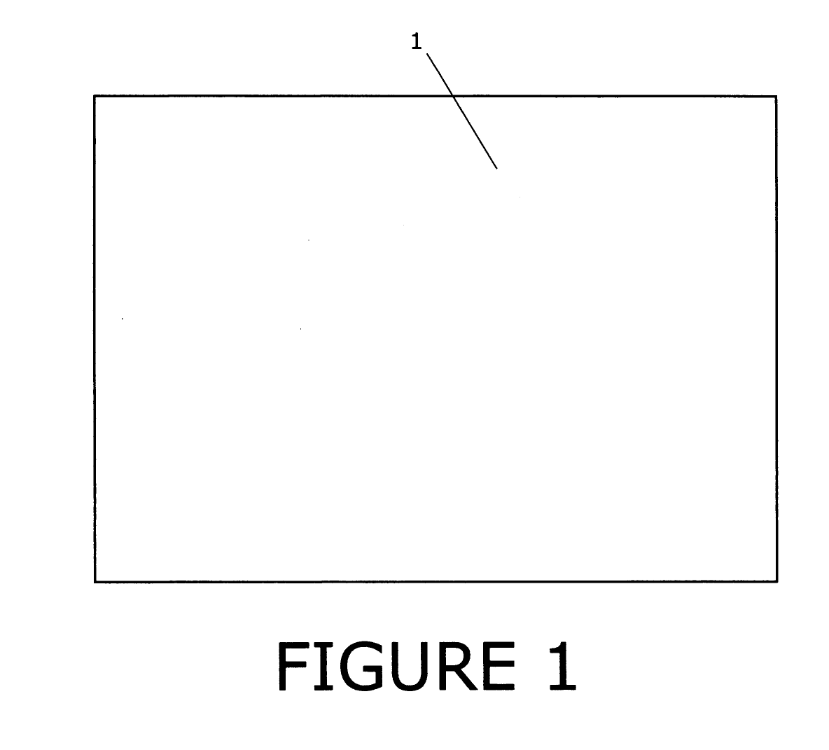

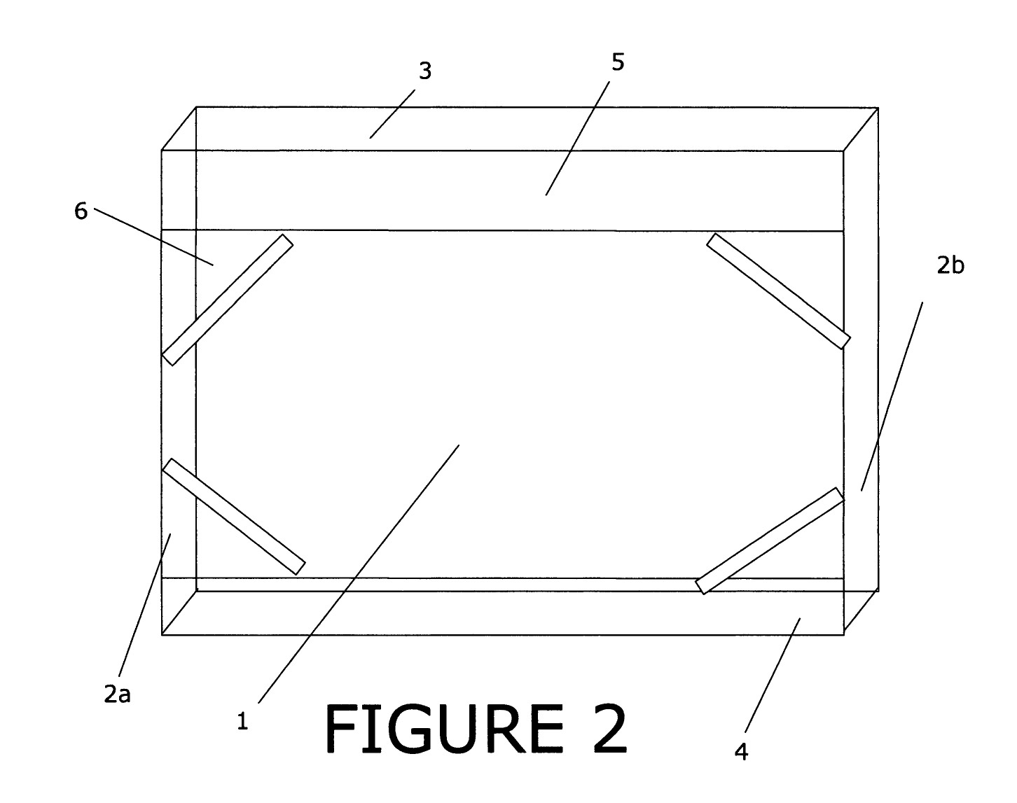

Referring now to FIGS. 1 and 2 there are shown one embodiment of the invention. A fabric material (1) covers the front face of monitor with side flaps (2a, 2b) and top flap (3) and bottom flap (4) of material that cover at least some portion of the sides and top and bottom of the visual display screen. Additional material is attached to the upper portion of the side-flaps and at least some portion of the top flap to form a “hood” (5). Bands (6) are attached diagonally over at least one corner on the backside of the cover.

In at least one embodiment, there are 2, 3 or 4 bands attached to the backside of the cover. In one embodiment, the bottom has no flap and is open. In one embodiment, the top hood extends until the brackets that support a wall or otherwise mounted visual display screen. In one embodiment, the material used is thick to conform to the surface of the visual display screen and ornamental like a tapestry with a pattern that is not symmetric or obviously repetitive to more closely resemble artwork. In one embodiment, visual display screen cover is connected to the visual display screen frame via Velcro strips. In one embodiment, visual display screen cover is connected to the visual display screen frame via fixing members including but not limited to snaps, screws, pins, magnets, and any combination thereof.

In at least one embodiment, the visual screen cover comprises material covering at least part of the visual screen cover that extends on top and over to the back of the visual screen and is secured by Velcro. In at least one embodiment, the visual screen cover comprises material covering at least part of the visual screen cover that extends on top and over to the back of the visual screen and is secured by straps. In at least one embodiment, a flap on the front cover opens to reveal the visual display screen. In one embodiment the suspending member and the front are constructed out of one piece of material. In one embodiment the suspending member, front and flap(s) are constructed out of one piece of material. In one embodiment the suspending member and the front are constructed out of several pieces of material. In at least one embodiment the suspending member, front and flap(s) are constructed out of several pieces of material.

In at least one embodiment, material is sized to cover at least part of front of visual display screen and secured to the face of visual display screen using straps or Velcro or hardware.

In at least one embodiment, material covers the front face of monitor with side-flaps and top flap and bottom flap of material that cover at least some portion of the sides and top and bottom of the visual display screen. Additional material is attached to the upper portion of the side-flaps and at least some portion of the top flap to form a “hood”. At least one zipper is used to allow for a tight fit and for easy installation and removal.

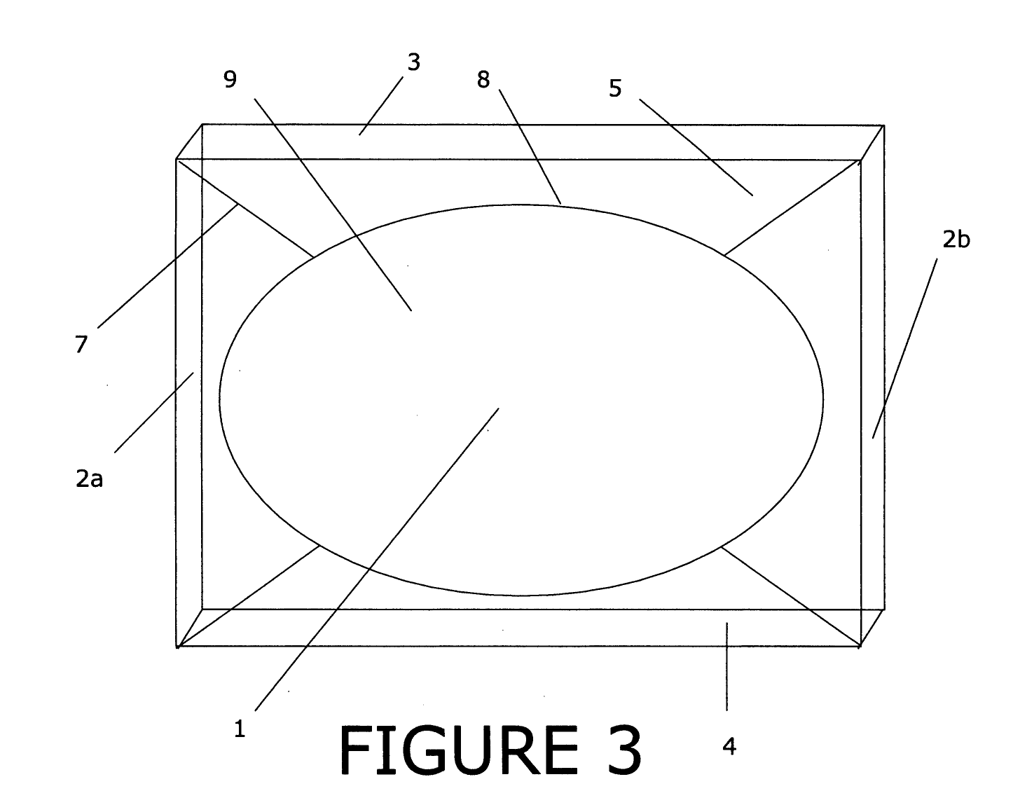

Referring now to FIG. 3 there is shown an embodiment which is constructed out of material (1) capable of stretching. The material may be one or more pieces constructed out of a material selected from: Lycra, Velour Stretch, Velvet Stretch, Spandex, Stretch knit and any combination thereof. The material may be capable of stretching the textile to be sized to conform to the visual display screen with extra to cover at least some portion of the sides, top and bottom of monitor. At least one seam (7) is sewn into a corner of the material to form a pocket and cling to the corners of the monitor. In at least one embodiment a strip (8) of material having a greater tension than the material (1) is positioned around an opening (9) in the back of the cover. In at least one embodiment at least a portion of the opening is shaped as a circle, oval, ellipse, square, rectangle, and any combination thereof. In at least one embodiment a drawstring runs along at least a portion of the opening and is constructed and arranged to appropriately tighten the fit of the cover against the display screen. In at least one embodiment the drawstring extends out of the rear of the cover.

In one embodiment, the visual screen cover desgined to match other home accessories including but not limited to one or a combination of the following household items: pillow, bedspread, blanket, throw cover, furniture, furniture cover, sheets, wallpaper, curtain, carpet and/or kitchen or other electrical appliance covers in matching, color coordinated or complimentary or contrasting patterns. In at least one embodiment, visual screen cover includes conductive material to reduce risk of static shock. In at least one embodiment, blank material is used to allow for customized artwork or decoration or silk screening process. In at least one embodiment, protective material is used to create visual screen cover to which decorative material or artwork is attached or printed. In at least one embodiment, religious picture, logo or text is utilized as decorative design. In at least one embodiment, commercial logo, picture or text is utilized as decorative design. In at least one embodiment, spiritual, philosophical or educational text, logo or visual are utilized as decorative design. Embodiments of the inventive concept include combinations of one, some, and all of the various components of each of the various Models described.

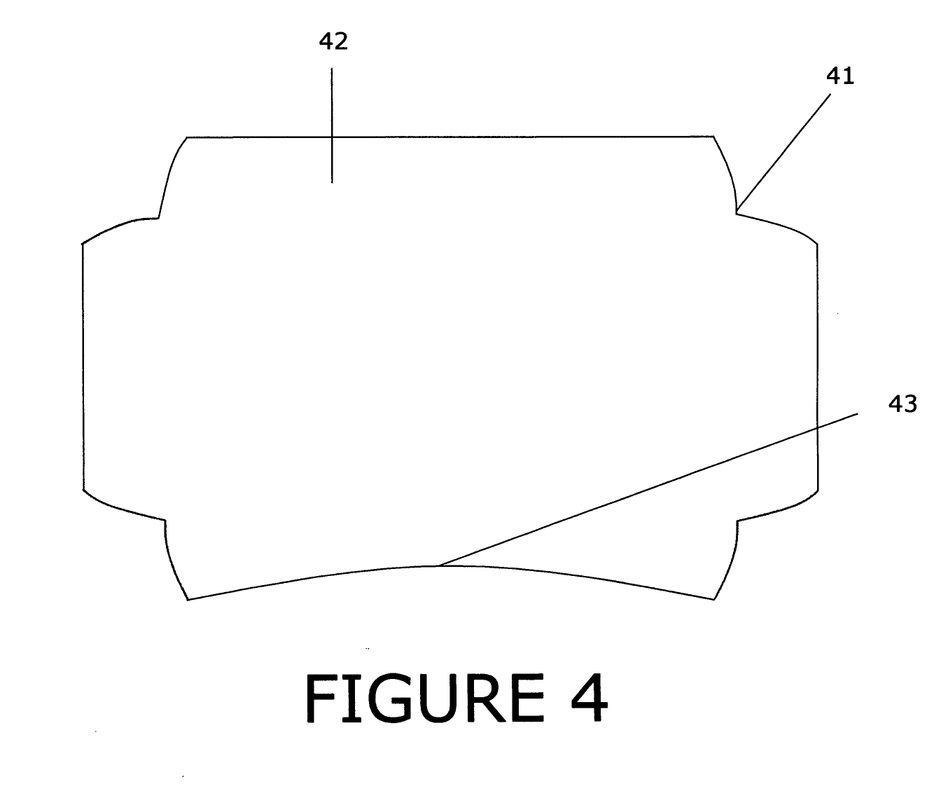

Referring now to FIG. 4 there is shown a cut out of material (42) useful in constructing the display cover. The corners (41) are cut at an angle designed so that the cover will cling tightly to the screen. This step is useful because the cover hangs vertically instead of horizontally and thus having it cling to the screen is an issue which this shape addresses. Also, the bottom (43) of the screen cover is cut in a rounded shape instead of a straight line to accommodate some screens which are thinner on the bottom than on top and/or have a stand to support them. This rounded cut also allows the screen cover to cling to the screen better and flatter.

While this invention may be embodied in many different forms, there described in detail herein specific preferred embodiments of the invention. The present disclosure is an exemplification of the principles of the invention and is not intended to limit the invention to the to particular embodiments illustrated. All patents, patent applications, scientific papers, and any other referenced materials mentioned herein are incorporated by reference in their entirety. Furthermore, the invention encompasses any possible combination of some or all of the various embodiments described herein and incorporated herein.

The above disclosure is intended to be illustrative and not exhaustive. This description will suggest many variations and alternatives to one of ordinary skill in this art. All these alternatives and variations are intended to be included within the scope of the claims where the term “comprising” means “including, but not limited to”. Those familiar with the art may recognize other equivalents to the specific embodiments described herein which equivalents are also intended to be encompassed by the claims.

All ranges and parameters disclosed herein are understood to encompass any and all subranges subsumed therein, and every number between the endpoints. For example, a stated range of “1 to 10” should be considered to include any and all subranges between (and inclusive of) the minimum value of 1 and the maximum value of 10; that is, all subranges beginning with a minimum value of 1 or more, (e.g. 1 to 6.1), and ending with a maximum value of 10 or less, (e.g. 2.3 to 9.4, 3 to 8, 4 to 7), and finally to each number 1, 2, 3, 4, 5, 6, 7, 8, 9, and 10 contained within the range.

This completes the description of the preferred and alternate embodiments of the invention. Those skilled in the art may recognize other equivalents to the specific embodiment described herein which equivalents are intended to be encompassed by the claims attached hereto.

1. A method for improving the esthetic appearance of a display screen, the method including the step of positioning over the display screen a decorative cover, the cover comprising
i) a front section constructed out of a flexible material,
ii) a rear section, the rear section having an upper section, a lower section, two side sections, each section engaged to the front surface and defining an opening, the opening positioned to surround a wall supporting member engaged to the display screen,
iii) the front section constructed and arranged to have sufficient tension to fit smoothly against the display screen's surface while positioned within a substantially vertical plane without any visible bunching up of the front section or ill-fitting irregularities,
iv) the upper section having a larger surface area than the bottom section and thereby facilitating in holding the front section smoothly against the display screen's surface
v) the front section having a decorative appearance.

2. The method of claim 1 wherein the front section and rear section are constructed out of a single piece of material.

3. The method of claim 2 wherein a seam in the upper section is engaged to the side sections along a seam in the material and the lower is engaged to the side sections along a seam in the material.

4. The method of claim 1 wherein the front section is constructed out of a stretchable material.

5. The method of claim 1 wherein the front section is constructed out of one selected from: Lycra, Velour Stretch, Velvet Stretch, Spandex, Stretch knit and any combination thereof.

6. The method of claim 1 wherein engaged along the opening is a strip of material having a greater tension than the front section, the strip constructed and arranged to pull the front section flush against the display screen.

7. The method of claim 1 wherein at least a portion of the opening is in a shape selected from: circle, oval, ellipse, square, rectangle, and any combination thereof.

8. The method of claim 1 wherein the cover further comprises a drawstring, the drawstring located along at least a portion of the opening and is constructed and arranged to appropriately tighten the fit of the front section against the display screen.

9. The method of claim 8. wherein the drawstring extends out of the rear of the cover.

10. The method of claim 1 wherein the display screen is one selected from: a TV, plasma screen, computer monitor, projector screen, and LCD display.

11. The method of claim 1 further comprising the step of positioning on at least one item of furniture in the same room as the cover a furniture cover having a similar pattern as that of the front section.
